(19) United States
(12) Patent Application Publication
(10) Pub. No.: US 2013/0155384 A1
(43) Pub. Date: Jun. 20, 2013

(54) EXPOSURE APPARATUS AND METHOD OF MANUFACTURING DEVICE

(71) Applicant: Canon Kabushiki Kaisha, Tokyo (JP)

(72) Inventor: Ryousuke Fukuoka, Utsunomiya-shi (JP)

(73) Assignee: CANON KABUSHIKI KAISHA, Tokyo (JP)

(21) Appl. No.: 13/714,244

(22) Filed: Dec. 13, 2012

(30) Foreign Application Priority Data
Dec. 15, 2011 (JP) PCT/JP2011/079044

(51) Int. Cl. G03F 7/20

(52) U.S. Cl. CPC G03F 7/70258
USPC 355/67

(57) ABSTRACT

An exposure apparatus for projecting an image of a pattern on a substrate and for exposing the substrate is disclosed. The exposure apparatus includes a mask stage and a projection optical system. The mask stage holds plural masks so that the plural masks do not contact with each other, and the projection optical system includes plural optical systems. Each of the optical systems projects an image of a pattern of one mask among the plural masks onto an exposure area of the substrate. The apparatus exposes the substrate so that each exposure area of the substrate exposed by each optical system partly overlaps with each other.

### BACKGROUND OF THE INVENTION

1. Field of the Invention

The present invention relates to an exposure apparatus and a method of manufacturing a device.

2. Background Art

An exposure apparatus is used for manufacturing a liquid crystal panel of FPD (Flat Panel Display). The exposure apparatus projects an image of a pattern of a mask on a glass substrate which a photoresist was applied to and exposes the glass substrate. Recently expansion of an exposure area to expose the glass substrate is expected in the exposure apparatus because the size of the glass substrate upsizes with upsizing of the liquid crystal panel.

Exposure apparatuses comprising a large exposure area are described in patent literatures 1-3. It is described in the patent literature 1 that imaging magnification of a reflection type projection optical system is bigger than 1. In the patent literature 2, arranging a plurality of projection lens systems in a cross direction (a direction perpendicular to a scanning direction of the glass substrate and the mask), the projection lens systems being two-stage of top and bottom and forming an erect image, and connecting each exposure area formed by each projection lens system of two-stage on the glass substrate are described. Arranging a plurality of unity magnification reflection type projection optical systems in the cross direction is described in the patent literature 3. In addition, connecting each exposure area formed by each reflection type projection optical system on the glass substrate using plural masks on each of which a mirror-reversed pattern is formed is described.

The reflection type projection optical system described in the patent literature 1 is high manufacturing cost and large due to enlarge imaging magnification. The projection lens system described in the patent literature 2 is large because the projection lens system described in the patent literature 2 is composed by two-stage of top and bottom to connect plural effective good imaging areas of an erect image on the substrate.

The reflection type projection optical system described in the patent literature 3 is unity magnification and is not composed by two-stage of top and bottom. The plural masks on which the mirror-reversed patterns are formed are arranged so as to contact with each other on one stage in the exposure apparatus described in the patent literature 3. The reflection type projection optical system projects a pattern of each mask directly underneath in vertical direction and forms each projection area. Therefore each exposure area exposed by scanning each projection area on the glass substrate is in a condition that adjacent exposure areas contact with each other. In other words an area (width) where exposure areas overlap with each other is not set. Therefore, in a pattern formed on glass substrate, defects such as discontinuous shape or step are generated in the area where each exposure area contacts with.

### CITATION LIST

### Patent Literature

PTL 1 Japanese Patent Laid-Open No. 2006-78592

PTL 2 Japanese Patent Laid-Open No. 7-57986

PTL 3 Japanese Patent Laid-Open No. 2003-84445

### SUMMARY OF THE INVENTION

According to at least one embodiment of the present invention, an exposure apparatus reduces the occurrence of a defect in connection of exposure patterns.

One aspect of the present invention is directed to an exposure apparatus for projecting an image of a pattern onto a substrate and for exposing the substrate, the apparatus comprising: a mask stage configured to hold plural masks so that the plural masks do not contact with each other; and a projection optical system configured to project the image of the pattern onto the substrate, wherein the projection optical system includes a plurality of optical systems, wherein each of the optical systems projects the image of the pattern of one mask among the plural masks onto an exposure area of the substrate, and wherein the apparatus exposes the substrate so that each exposure area of the substrate exposed by each optical system partly overlaps with each other.

Further features of the present invention will become apparent from the following description of exemplary embodiments with reference to the attached drawings.

### BRIEF DESCRIPTION OF THE DRAWINGS

FIG. 1 is a view from a side of a mask surface showing constitution around a projection optical system of an exposure apparatus according to the first embodiment.

FIG. 2 is a side view of showing constitution around a projection optical system of according to the first embodiment.

FIG. 3 is a view from a side of a frustum-shaped mirror showing constitution around a projection optical system of according to the first embodiment.

FIG. 4 is a view from a side of a mask surface showing constitution around a projection optical system of an exposure apparatus according to the second embodiment.

FIG. 5 is a side view of showing constitution around a projection optical system of according to the second embodiment.

FIG. 6 is a view from the y direction (left direction in FIG. 4) showing constitution around a projection optical system of according to the second embodiment.

FIG. 7 is a view from a side of a mask surface showing constitution around a projection optical system of an exposure apparatus according to the third embodiment.

FIG. 8 is a side view of showing constitution around a projection optical system of according to the third embodiment.

FIG. 9 is a view from the y direction (left direction in FIG. 7) showing constitution around a projection optical system of according to the third embodiment.

### DESCRIPTION OF THE EMBODIMENTS

### First Embodiment

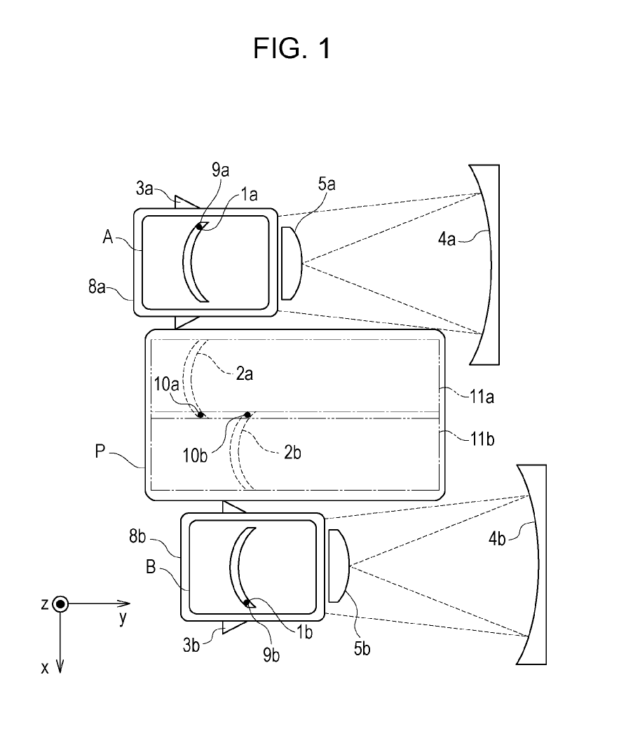

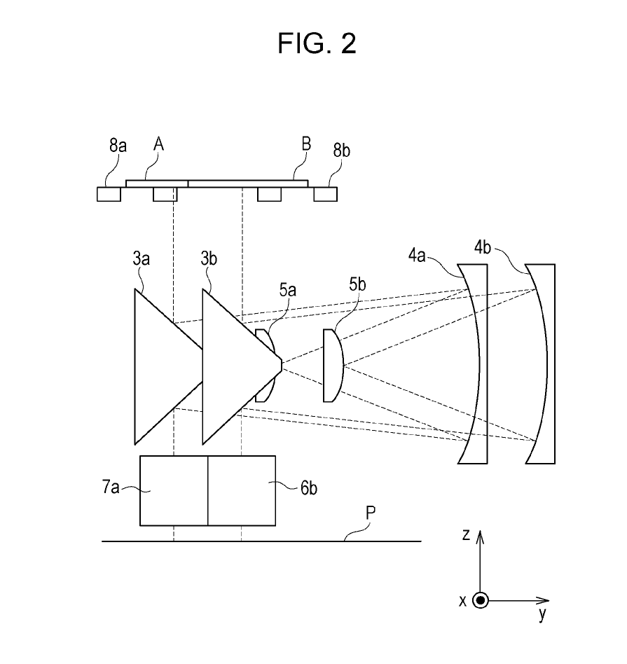

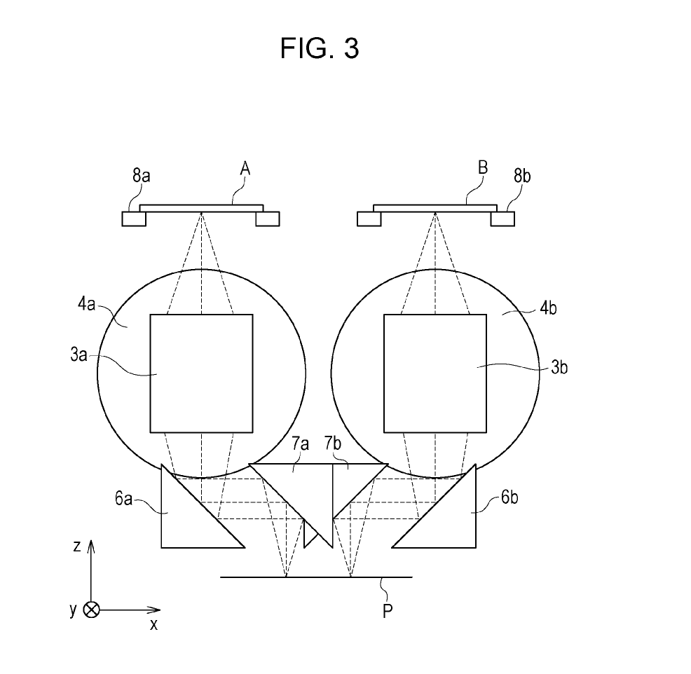

FIG. 1 is a view from a side of a mask surface showing constitution around a projection optical system of an exposure apparatus according to the present embodiment. FIG. 2 is a side view (a view from the x direction (downward direction in FIG. 1)). FIG. 3 is a view from a side of a frustum-shaped mirror. In FIG. 1, reflecting prisms 6a, 6b, 7a and 7b to be described below are omitted.

An exposure apparatus according to the present embodiment projects images of patterns of at least two masks (mask A, B) onto one substrate P.

A mask stage 8a holds the mask A and moves the mask A and a mask stage 8b holds the mask B and moves the mask B. The mask stages 8a and 8b are illustrated as separate stages for ease of illustration, it is envisioned that a single mask stage may be configured to hold and move a plurality of masks independently. In other words these mask stages may be implemented as a single mask stage to hold plural masks so that the plural masks do not contact with each other. The substrate P is held by a substrate stage (not shown in these figures). The exposure apparatus according to the present embodiment is a scanning-type exposure apparatus which illuminates each mask while moving each mask and the substrate P in the y direction (a scanning direction) and exposes the substrate P to radiative energy.

The exposure apparatus comprises an illumination optical system not shown in a figure. The illumination optical system illuminates each of the mask A and mask B using light from a light source. The illumination optical system illuminates each mask with illumination light, the cross section of the illumination light being arc-shaped. The illumination optical system forms an arc-shaped illumination area 1a and an arc-shaped illumination area 1b. The light source and the illumination optical system are constituted by well-known technology. When independent light sources are used, each light source and each illumination optical system can be arranged corresponding to each mask. Alternatively, when a single light source is used, means configured to divide light from one light source by, for example, a fiber and so on, and optics to illuminate each mask can be used.

The exposure apparatus comprises a plurality of reflection type projection optical systems (optical systems) corresponding to the plural masks. Each projection optical system has an Offer configuration (a projection optical system of magnification 1 time) and provides good imaging arc-shaped area with minimum aberration. In this embodiment, the plural projection optical systems have the same optical constant (a radius of curvature, an air interval, index of refraction).

The projection optical system which projects an image of a pattern of the mask A on the substrate P comprises a frustum-shaped mirror 3a, a concave mirror 4a, a convex mirror 5a, a reflecting prism (rectangular prism) 6a and a reflecting prism (rectangular prism) 7a. Seeing the mirror 3a from the x direction, the mirror 3a is trapezoid-shaped as shown in FIG. 2. Light from the mask is shown in a dotted line in FIGS. 1-3. The projection optical system projecting the image of the pattern of the mask A on the substrate P reflects light from the mask A in order of the first flat reflecting surface of the frustum-shaped mirror 3a, the first concave reflecting surface of the concave mirror 4a, a convex reflecting surface of the convex mirror 5a, the second concave reflecting surface of the concave mirror 4a, and the second flat reflecting surface of the mirror 3a. Furthermore, light having been reflected by the second flat reflecting surface of the mirror 3a is reflected by a flat reflecting surface of the reflecting prisms 6a and 7a. And the second flat reflecting surface of the mirror 3a changes the direction of light path. The flat reflecting surface of the reflecting prism 6a and 7a are arranged to face each other such that the respective reflecting surfaces are parallel, as shown in FIG. 3. Path of light having entered the reflecting prism 6a is changed to the x direction and light having entered the reflecting prism 6a enters the reflecting prism 7a as shown in FIG. 3. The reflecting prism 7a changes the light path to—z direction.

Also, the projection optical system projecting an image of a pattern of the mask B on the substrate P comprises a frustum-shaped mirror 3b, a concave mirror 4b, a convex mirror 5b, a reflecting prism 6b and a reflecting prism 7a. The projection optical system projecting the image of the pattern of the mask B on the substrate P reflects light from the mask B in order of the first flat reflecting surface of the mirror 3b, the first concave reflecting surface of the concave mirror 4b, a convex reflecting surface of the convex mirror 5b, the second concave reflecting surface of the concave mirror 4b, and the second flat reflecting surface of the reflecting mirror 3b. Furthermore, light having been reflected by the second flat reflecting surface of the reflecting mirror 3b is reflected by a flat reflecting surface of the reflecting prisms 6b and 7b. And the direction of light reflected by the second flat reflecting surface of the reflecting mirror 3b is changed as shown in FIG. 3.

A radius of curvature of the first concave reflecting surface of the concave mirror 4a is the same as a radius of the second concave reflecting surface of the concave mirror 4a. The first concave reflecting surface and the second concave reflecting surface of the concave mirror 4b have the same radius of curvature, too.

Each projection optical system projects light reflected by the flat reflecting surface of the reflecting prism on the substrate P and forms arc-shaped projection areas 2a and 2b where an image of a pattern of each mask is projected on the substrate P (image plane). And the substrate P is exposed by scanning the projection area on the substrate while moving each mask and the substrate P in the scanning direction.

A pattern of each mask turns over like a mirror-reversed pattern, and the pattern of each mask is exposed on a substrate because each projection optical system is configured as an Offner optical system. Therefore it is necessary to reverse the pattern of each mask to be connected so that a pattern has continuity on a substrate, that is, without a pattern breaking off. For example, in FIG. 1, an area 9a shown with round shape on the mask A is transferred on an area 10a of the substrate P, and an area 9b shown with square shape on the mask B is transferred on an area 10b of the substrate P.

The illumination areas 1a and 1b of the mask are shifted by a predetermined distance in the scanning direction as shown in FIG. 1. Therefore the projection areas 2a and 2b do not have an area overlapped with each other on the substrate. An exposure area 11a of the substrate exposed by scanning the projection area 2a on the substrate and an exposure area 11b of the substrate exposed by scanning the projection area 2b on the substrate, while moving the mask and the substrate in the scanning direction, are partly overlapped with each other. The exposure area 11a is an area shown in two points of dot-dash lines of FIG. 1, and the exposure area 11b is an area shown in one point of dot-dash line of FIG. 1. The width (length in the direction (the x direction) perpendicular to the scanning direction) of area overlapped by each exposure area is able to be changed by arrangement (position and angle) of the reflecting prisms 6a, 6b, 7a, and 7b. For example, the width of the overlapped area of each exposure area is changed by moving the prisms 7a and 7b in the x direction.

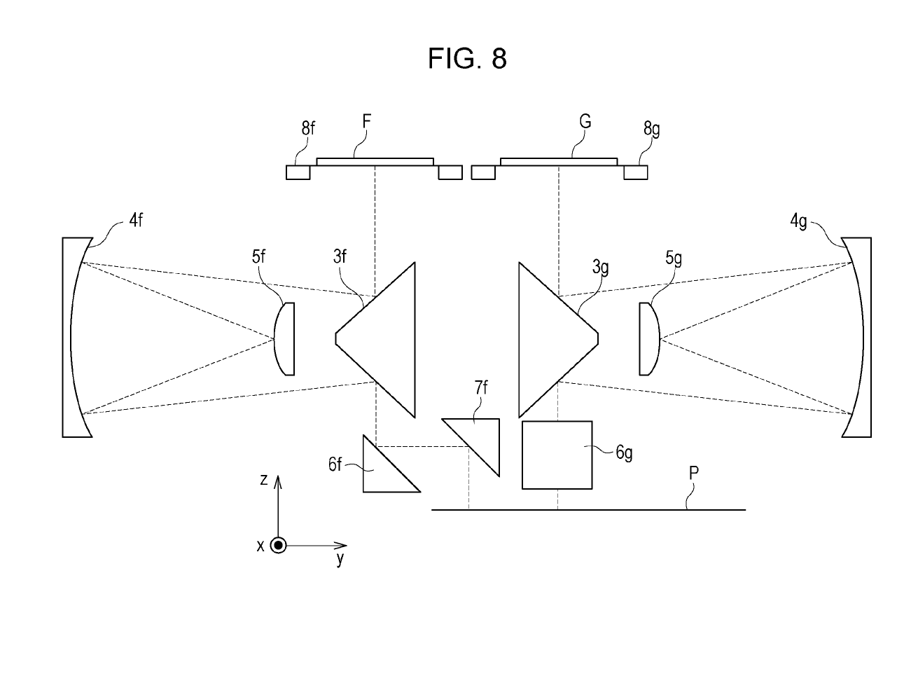

It is necessary to make integrated exposures amount in an overlapped area and in an area except the overlapped area same to uniform an integrated exposure amount at each position in the exposure area on the substrate. Therefore light intensity at the edge of each projection area (ex. the areas 10a, 10b) is set to become lower than light intensity in other area. Or the width in the scanning direction at the edge of each projection area is formed to be narrower. In regard to formation of a light intensity distribution, well-known technology can be used as mentioned in FIG. 8 and so on of above patent literature 2.

In this embodiment, the illumination areas 1a and 1b (projection areas 2a and 2b) of the mask are shifted in the scanning direction and optical members are placed so that physical interference among the optical members is avoided. Therefore, the width of the overlapped area by each exposure area may be changed to an arbitrary value. The illumination areas 1a and 1b of the masks can be placed without shift in the scanning direction.

The reflecting prisms 6a, 6b, 7a and 7b bend a light beam to transfer with connecting the patterns of the two separated masks A and B on the one substrate P. The illumination area of the mask and the projection area on the substrate are shifted as shown in FIG. 1. That is, the reflecting prisms 6a, 6b, 7a and 7b have a function to form the projection area of the pattern on the substrate at a position different from a position where the illumination area of the mask is extended in the vertical direction. Seeing the projection optical system from an object side (top surface), the positions in the illumination area of the mask and the projection area of the pattern are different. In this embodiment, a position where the illumination area of the mask is extended in the vertical direction and a position of the projection area of the pattern are shifted in the direction (the x direction) perpendicular to the scanning direction (the y direction) in the xy plane (movement plane of the substrate or movement plane of the mask). In other words, the position where the illumination area of the mask is extended in the vertical direction and the position of the projection area of the pattern are the same in the y direction and different in the x direction.

As mentioned above, in this embodiment, the overlapped area of each exposure area may be set by holding the masks so as not to contact with each mask and bending light with the reflecting prism. Therefore, in case that the pattern of each mask is transferred on the one substrate, a defect such as discontinuous shape or step is not likely generated. And an occurrence of connection error with patterns is decreased.

### Second Embodiment

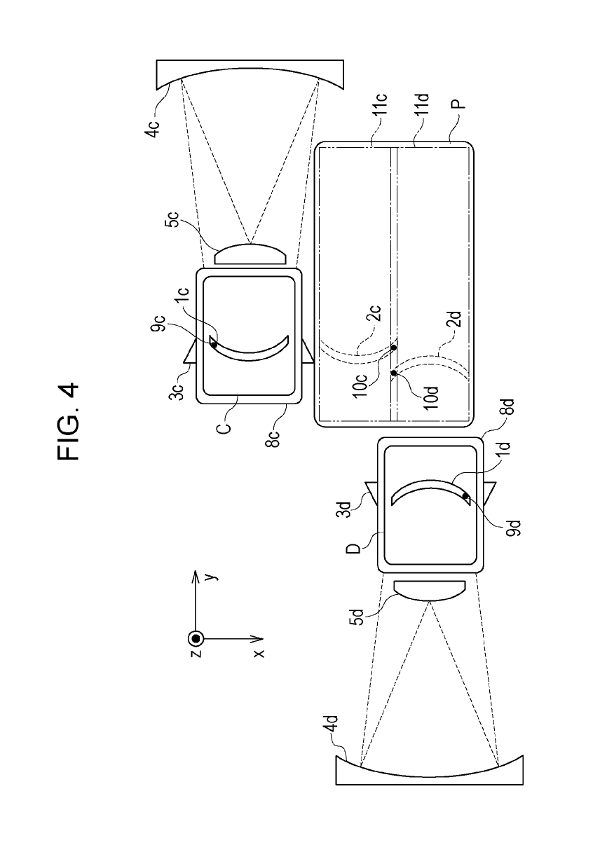

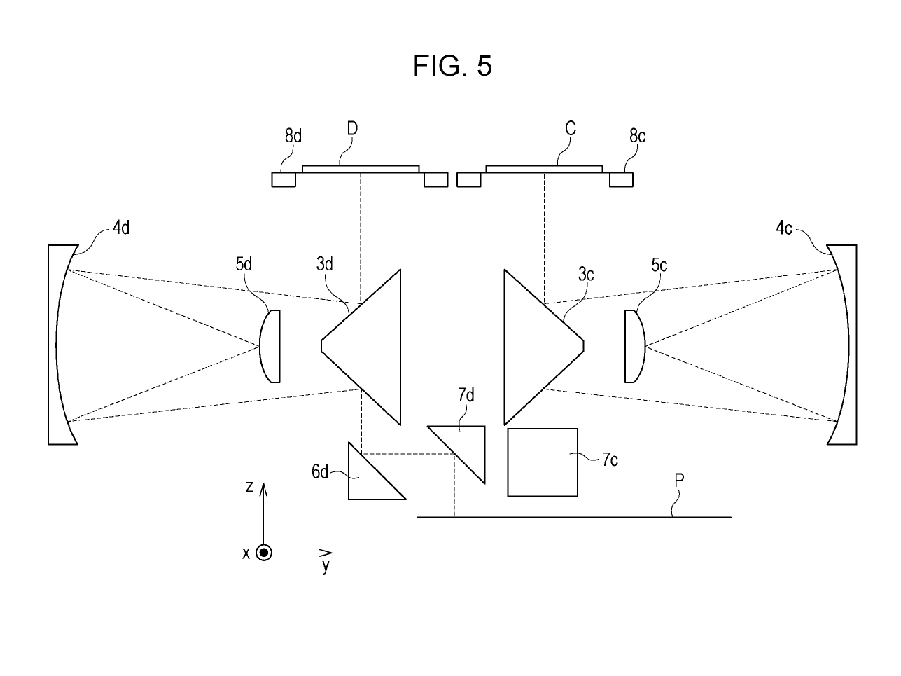

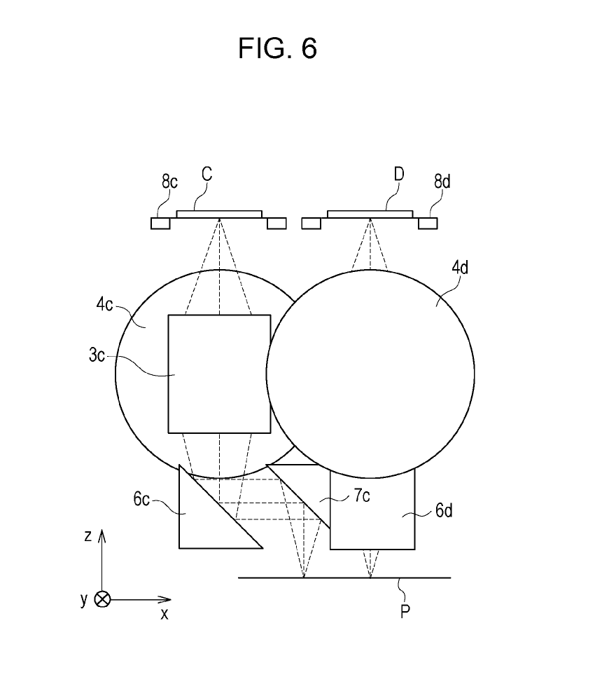

FIG. 4 is a view from a side of a mask surface showing constitution around a projection optical system of an exposure apparatus according to the present embodiment. FIG. 5 is a side view (a view from the x direction (downward direction in FIG. 4)). FIG. 6 is a view from the y direction (left direction in FIG. 4). In FIG. 4, reflecting prisms 6c, 6d, 7c and 7d to be described are omitted.

In this embodiment, the placement of the projection optical system and a mask is different compared with the first embodiment. Explanation of constitutions same to the first embodiment is omitted. In case that an optical specification such as the size of the exposure area is changed in the first embodiment, the concave mirrors are likely to hit each other when moving the concave mirrors. Therefore, in this embodiment, the concave mirrors are placed so that there is no interference of the concave mirrors.

A mask stage 8c holds a mask C and moves the mask C and a mask stage 8d holds a mask D and moves the mask D. In other words these mask stages hold masks so that plural masks do not contact with each other. The exposure apparatus according to the present embodiment illuminates each mask while moving each mask and the substrate P in the y direction (a scanning direction) and exposes the substrate P.

An illumination optical system illuminates the mask C and D using light from a light source. The illumination optical system illuminates each mask with illumination light, the cross section of the illumination light being arc-shaped. The illumination optical system forms an arc-shaped illumination area 1c and an arc-shaped illumination area 1d.

A projection optical system projecting an image of a pattern of the mask C on the substrate P comprises a frustum-shaped mirror 3c, a concave mirror 4c, a convex mirror 5c, a reflecting prism 6c and a reflecting prism 7c. Light from the mask is shown in a dotted line in FIGS. 4-6. The projection optical system projecting the image of the pattern of the mask C on the substrate P reflects light from the mask in order of the first flat reflecting surface of the mirror 3c, the first concave reflecting surface of the concave mirror 4c, a convex reflecting surface of the convex mirror 5c, the second concave reflecting surface of the concave mirror 4c, and the second flat reflecting surface of the mirror 3c. Furthermore, light having been reflected by the second flat reflecting surface of the mirror 3c is reflected by a flat reflecting surface of the reflecting prisms 6c and 7c. And the second flat reflecting surface of the mirror 3c changes the direction of light. Path of light having entered the reflecting prism 6c is changed to the x direction and light having entered the reflecting prism 6c enters the reflecting prism 7c as shown in FIG. 6. The reflecting prism 7c changes light path to—z direction.

Also, a projection optical system projecting an image of a pattern of the mask D on the substrate P comprises a frustum-shaped mirror 3d, a concave mirror 4d, a convex mirror 5d, a reflecting prism 6d and a reflecting prism 7d. The projection optical system projecting the image of the pattern of the mask D on the substrate P reflects light from the mask in order of the first flat reflecting surface of the mirror 3d, the first concave reflecting surface of the concave mirror 4d, a convex reflecting surface of the convex mirror 5d, the second concave reflecting surface of the concave mirror 4d, and the second flat reflecting surface of the reflecting mirror 3d. Furthermore, light having been reflected by the second flat reflecting surface of the reflecting mirror 3d is reflected with a flat reflecting surface of the reflecting prisms 6d and 7d. And the second flat reflecting surface of the mirror 3d changes the direction of light as shown in FIG. 5. Path of light having entered the reflecting prism 6d is changed to the y direction and light having entered the reflecting prism 6d enters the reflecting prism 7d. The reflecting prism 7d changes light path to—z direction.

The first concave reflecting surface and the second concave reflecting surface of the concave mirror 4c have the same radius of curvature. The first concave reflecting surface and the second concave reflecting surface of the concave mirror 4d have the same radius of curvature, too.

Each projection optical system projects light reflected by the flat reflecting surface of the reflecting prism on the substrate P and forms arc-shaped projection areas 2c and 2d where an image of a pattern of each mask is projected on the substrate P (image plane). And the substrate P is exposed by scanning each projection area on the substrate while moving each mask and the substrate P in the scanning direction.

In FIG. 4, an area 9c shown with round shape on the mask C is transferred on an area 10c of the substrate P, and an area 9d shown with square shape on the mask D is transferred on an area 10d of the substrate P.

The illumination areas 1c and 1d of the mask are shifted by a predetermined distance in the scanning direction as shown in FIG. 4. Furthermore the projection areas 2c and 2d do not have an area overlapped with each other on the substrate by the function of the reflecting prism. An exposure area 11c of the substrate exposed by scanning the projection area 2c on the substrate and an exposure area 11d of the substrate exposed by scanning the projection area 2d on the substrate, while moving the mask and the substrate in the scanning direction, are partly overlapped with each other. The exposure area 11c is an area shown in two points of dot-dash lines of FIG. 4, and the exosure area 11d is an area shown in one point of dot-dash line of FIG. 4. The width (length in the direction (the x direction) perpendicular to the scanning direction) of the area overlapped by each exposure area is able to be changed by arrangement of the reflecting prisms 6c, 6d, 7c, and 7d. For example, the width of the overlapped area of each exposure area is changed by moving the prism 7c in the x direction.

To uniform an integrated exposure amount at each position of the exposure area on the substrate, light intensity at the edge of each projection area (ex. the areas 10a, 10b) is set to become smaller than light intensity in other area. Or the width in the scanning direction at the edge of each projection area is formed to be narrower.

The reflecting prisms 6c, 6d, 7c and 7d bend a light beam to transfer with connecting the patterns of the two separated masks C and D on the one substrate P. The illumination area of the mask and the projection area on the substrate are shifted shown in FIG. 4. That is, each reflecting prism has a function to form the projection area of the pattern on the substrate at a position different from a position where the illumination area of the mask is extended in the vertical direction. Concretely, as respect to the projection area 2c, a position where the illumination area 1c of the mask is extended in the vertical direction and a position of the projection area of the pattern are shifted in the direction (the x direction) perpendicular to the scanning direction in the xy plane. As respect to the projection area 2d, a position where the illumination area 1d of the mask is extended in the vertical direction and a position of the projection area of the pattern are shifted in the scanning direction (the y direction) in the xy plane.

Above mentioned, in this embodiment, the overlapped area of each exposure area is able to be sufficiently set by holding so as not to contact with each mask and bending light with the reflecting prism. Therefore, in case that the pattern of each mask is transferred on the one substrate, an occurrence of connection error with patterns is decreased. In addition, the interference of the concave mirrors is reduced in this embodiment.

### Third Embodiment

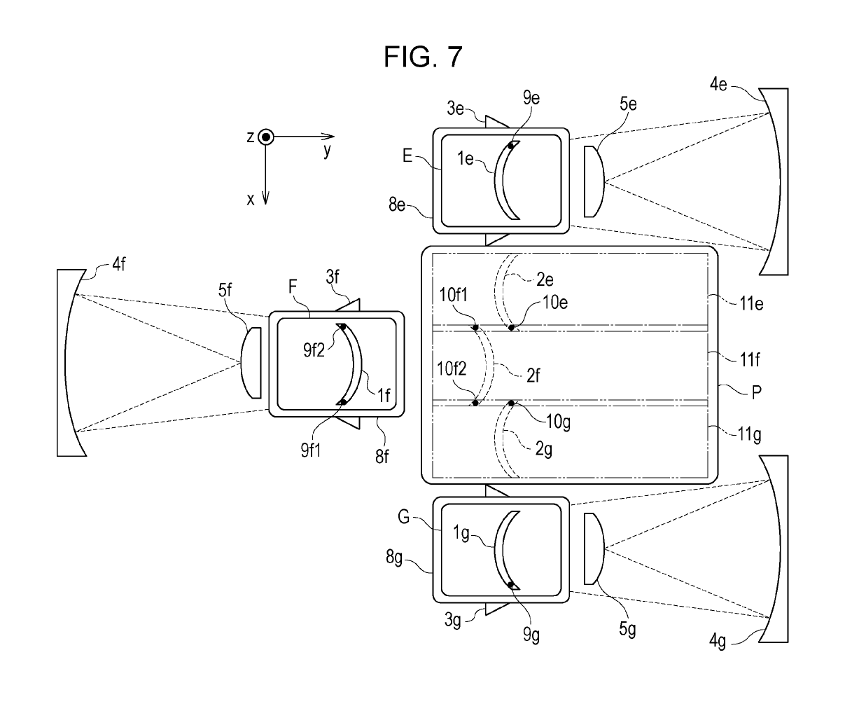

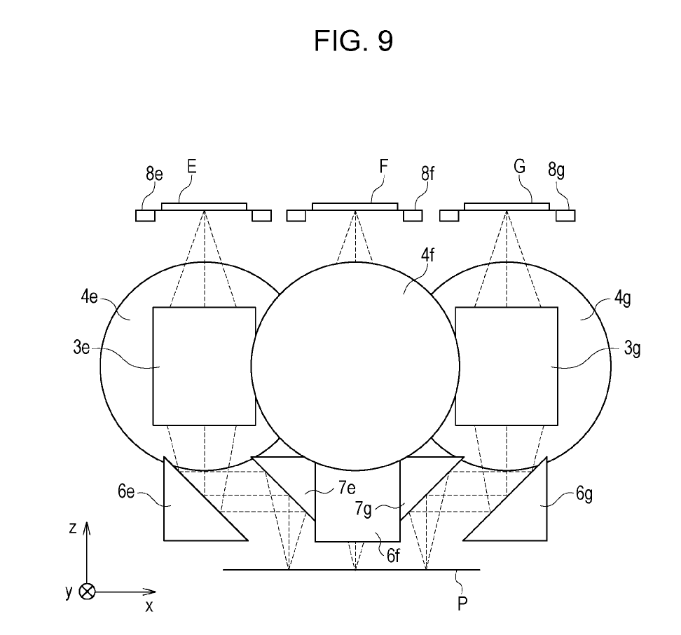

FIG. 7 is a view from a side of a mask surface showing constitution around a projection optical system of an exposure apparatus according to the present embodiment. FIG. 8 is a side view (a view from the x direction (downward direction in FIG. 7)). FIG. 9 is a view from the y direction (left direction in FIG. 7). In FIG. 7, reflecting prisms 6e-g, 7e-g to be described are omitted.

In this embodiment, the placement of the projection optical system and a mask is different compared with the first and second embodiment. Explanation of constitutions same to the above embodiment is omitted. In this embodiment, the concave mirrors are placed not to interfere as is the case in the second embodiment.

The exposure apparatus according to this embodiment exposes an image of a pattern of three mask (masks E, F, G) on the one substrate P.

A mask stage 8e holds and moves the mask E and a mask stage 8f holds and moves the mask F. A mask stage 8g holds and moves the mask G. In other words these mask stages hold masks so that plural masks do not contact with each other. The exposure apparatus according to the present embodiment illuminates each mask while moving each mask and the substrate P in the y direction (a scanning direction) and exposes the substrate P.

An illumination optical system illuminates the mask E, F, and G using light from a light source. The illumination optical system illuminates each mask with illumination light, the cross section of the illumination light being arc-shaped. The illumination optical system forms an arc-shaped illumination area 1e, an arc-shaped illumination area 1f, and an arc-shaped illumination area 1g.

A projection optical system projecting an image of a pattern of the mask E on the substrate P comprises a frustum-shaped mirror 3e, a concave mirror 4e, a convex mirror 5e, a reflecting prism 6e and a reflecting prism 7e. Light from the mask is shown in a dotted line in FIGS. 7-9. The projection optical system projecting the image of the pattern of the mask E on the substrate P reflects light from the mask in order of the first flat reflecting surface of the mirror 3e, the first concave reflecting surface of the concave mirror 4e, a convex reflecting surface of the convex mirror 5e, the second concave reflecting surface of the concave mirror 4e, and the second flat reflecting surface of the mirror 3e. Furthermore, light having been reflected by the second flat reflecting surface of the mirror 3e is reflected by a flat reflecting surface of the reflecting prisms 6e and 7e. And the second flat reflecting surface of the mirror 3e changes the direction of light. Path of light having entered the reflecting prism 6e is changed to the x direction and light having entered the reflecting prism 6e enters the reflecting prism 7e as shown in FIG. 9. The reflecting prism 7e changes light path to—z direction.

Also, a projection optical system projecting an image of a pattern of the mask F on the substrate P comprises a frustum-shaped mirror 3f, a concave mirror 4f, a convex mirror 5f, a reflecting prism 6f and a reflecting prism 7f. The projection optical system projecting the image of the pattern of the mask F on the substrate P reflects light from the mask in order of the first flat reflecting surface of the mirror 3f, the first concave reflecting surface of the concave mirror 4f, a convex reflecting surface of the convex mirror 5f, the second concave reflecting surface of the concave mirror 4f, and the second flat reflecting surface of the reflecting mirror 3f. Furthermore, light having been reflected by the second flat reflecting surface of the reflecting mirror 3f is reflected with a flat reflecting surface of the reflecting prisms 6f and 7f. And the second flat reflecting surface of the mirror 3f changes the direction of light as shown in FIG. 8. Path of light having entered the reflecting prism 6f is changed to the y direction and light having entered the reflecting prism 6f enters the reflecting prism 7f. The reflecting prism 7f changes light path to—z direction.

A projection optical system projecting an image of a pattern of the mask G on the substrate P comprises a frustum-shaped mirror 3g, a concave mirror 4g, a convex mirror 5g, a reflecting prism 6g and a reflecting prism 7g. The projection optical system projecting the image of the pattern of the mask G on the substrate P reflects light from the mask in order of the first flat reflecting surface of the mirror 3g, the first concave reflecting surface of the concave mirror 4g, a convex reflecting surface of the convex mirror 5g, the second concave reflecting surface of the concave mirror 4g, and the second flat reflecting surface of the reflecting mirror 3g. Furthermore, light having been reflected by the second flat reflecting surface of the reflecting mirror 3g is reflected with a flat reflecting surface of the reflecting prisms 6g and 7g. And the second flat reflecting surface of the mirror 3g changes the direction of light. As shown in FIG. 9, path of light having entered the reflecting prism 6g is changed to the x direction and light having entered the reflecting prism 6g enters the reflecting prism 7g. The reflecting prism 7g changes light path to—z direction.

The first concave reflecting surface and the second concave reflecting surface of the concave mirror 4e have the same radius of curvature. The same is true on the concave mirror 4f and 4g.

Each projection optical system projects light reflected by the flat reflecting surface of the reflecting prism on the substrate P and forms arc-shaped projection areas 2e, 2f, and 2g where an image of a pattern of each mask is projected on the substrate P (image plane). And the substrate P is exposed by scanning each projection area on the substrate while moving each mask and the substrate P in the scanning direction.

In FIG. 7, an area 9e shown with form of round shape on the mask E is transferred on an area 10e of the substrate P, and an area 9f1 shown with round shape on the mask F is transferred on an area 10f1 of the substrate P. An area 9f2 shown with square shape on the mask F is transferred on an area 10f2 of the substrate P, and an area 9g shown with square shape on the mask G is transferred on an area 10g of the substrate P.

Comparing with the illumination areas 1e, 1g and the illumination area 1f of the mask, these are shifted by a predetermined distance in the scanning direction as shown in FIG. 7. Furthermore the projection areas 2e, 2f, and 2g do not have an area overlapped with each other on the substrate by the function of the reflecting prism. An exposure area 11e of the substrate exposed by scanning the projection area 2e on the substrate and an exposure area 11f of the substrate exposed by scanning the projection area 2f on the substrate, while moving the mask and the substrate in the scanning direction, are partly overlapped each other. The exposure area 11e is an area shown in two points of dot-dash lines of FIG. 7, and the exposure area 11f is an area shown in one point of dot-dash line of FIG. 4. Also, the exposure area 11f and an exposure area 11g (an area shown in two points of dot-dash lines of FIG. 7) of the substrate exposed by scanning the projection area 2g on the substrate are partly overlapped each other.

The width (length in the direction (the x direction) perpendicular to the scanning direction) of the area overlapped by each exposure area is able to be changed by arrangement of the reflecting prisms 6e to g, 7e to g. For example, the width of the overlapped area of each exposure area is changed by moving the prisms 7e and 7g in the x direction.

To uniform an integrated exposure amount at each position of the exposure area on the substrate, light intensity at the edge of each projection area is set to become smaller than light intensity in other area. Or the width in the scanning direction at the edge of each projection area is formed to be narrower.

The reflecting prisms 6e to g and 7e to g bend a light beam to transfer with connecting the patterns of the three separated masks E to G on the one substrate P. The illumination area of the mask and the projection area on the substrate are shifted shown in FIG. 7. That is, each reflecting prism has a function to form the projection area of the pattern on the substrate at a position different from a position where the illumination area of the mask is extended in the vertical direction. Concretely, as respect to the projection area 2e, a position where the illumination area 1e of the mask is extended in the vertical direction and a position of the projection area 2e of the pattern are shifted in the direction (the x direction) perpendicular to the scanning direction in the xy plane. The same is true on the projection area 2g. As respect to the projection area 2f, a position where the illumination area 1f of the mask is extended in the vertical direction and a position of the projection area 2f of the pattern are shifted in the scanning direction (the y direction) in the xy plane.

Above mentioned, in this embodiment, the overlapped area of each exposure area is able to be sufficiently set by holding so as not to contact with each mask and bending light with the reflecting prism. Therefore, in case that the pattern of each mask is transferred on the one substrate, an occurrence of connection error with patterns is decreased. In addition, the interference of the concave mirrors is reduced in this embodiment.

In the above embodiments, cases to connect the patterns of two or three masks are exemplified, it is possible to increase the number of the projection optical system and to connect patterns of masks more than 4.

The one mask stage has held the one mask. However, it is possible to set plural mask holding frames on the one mask stage, to place the mask in the holding frame, and to hold the plural masks so that the plural masks do not contact with each other.

In the above embodiments, cases of the plural mask stages which hold to be able to independently move each of the plural masks are exemplified, it is possible to hold all masks by the one mask stage if the one mask stage can hold without contacting each mask.

In the above embodiments, the scanning type exposure apparatuses are exemplified, a step-and-repeat type exposure apparatus (stepper) is applicable. In addition, the projection optical system is not limited to unity magnification, an enlargement system or a reduction system is applicable. The projection optical system is not limited to a reflection type, a transmissive type (lenses) optical system is applicable. In addition, an optical member which bend an optical path is sufficient as the above reflecting prism, a right surface reflecting mirror or a total reflecting mirror is applicable.

### Fourth Embodiment

Next, a method of manufacturing a device (a semiconductor IC device, a liquid crystal display device and so on) using the above-mentioned exposure apparatus will be described. The device is manufactured by a step of exposing a substrate (a wafer, a glass substrate, and so on) coated with a photoresist using the above-mentioned exposure apparatus, a step of developing the substrate (the photoresist), and other well-known steps. The other well-known steps include etching, photoresist striping, dicing, bonding, packaging and so on. This method of manufacturing a device can manufacture a device with a quality higher than those of devices manufactured by the related art techniques.

The present invention allows for reducing an occurrence of a defect in connection with patterns.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of International Application No. PCT/JP2011/079044, filed Dec. 15, 2011, which is hereby incorporated by reference herein in its entirety.

What is claimed is:

1. An exposure apparatus for projecting an image of a pattern onto a substrate and for exposing the substrate, the apparatus comprising:
a mask stage configured to hold plural masks so that the plural masks do not contact with each other; and
a projection optical system configured to project the image of the pattern on the substrate,
wherein the projection optical system includes a plurality of optical systems,
wherein each of the optical systems projects the image of the pattern of one mask among the plural masks onto an exposure area of the substrate, and
wherein the apparatus exposes the substrate so that each exposure area of the substrate exposed by each optical system partly overlaps with each other.

2. The apparatus according to claim 1, wherein at least one of the plurality of the optical systems forms a projection area where the pattern of the mask is projected onto the substrate at a position different from a position where an illumination area of the mask is extended in the vertical direction.

3. The apparatus according to claim 2, wherein the apparatus is a scanning type exposure apparatus which expose the substrate while scanning the substrate and the mask in a scanning direction,
wherein the position where an illumination area of the mask is extended in the vertical direction and the projection area where the pattern of the mask is projected onto the substrate are different in the scanning direction.

4. The apparatus according to claim 2, wherein the apparatus is a scanning type exposure apparatus which exposes the substrate while scanning the substrate and the mask in a scanning direction,
wherein the position where an illumination area of the mask is extended in the vertical direction and the projection area where the pattern of the mask is projected onto the substrate are different in a direction perpendicular to the scanning direction.

5. The apparatus according to claim 2, wherein the projection optical system comprises a optical member configured to bend a light path,
wherein the projection area where the pattern of the mask is projected on the substrate is formed at a position different from a position where an illumination area of the mask is extended in the vertical direction using the optical member.

6. The apparatus according to claim 1, further comprising a plurality of the mask stages configured to hold so as to move independently each of the plurality of the masks.

7. The apparatus according to claim 1, wherein the projection optical system is a reflection type projection optical system.

8. The apparatus according to claim 5, wherein the optical member comprises a flat reflecting surface.

9. A method of manufacturing a device, the method comprising:
exposing a substrate using an exposure apparatus; and
developing the exposed substrate,
wherein the exposure apparatus projects an image of a pattern onto the substrate and exposes the substrate,
wherein the exposure apparatus comprises:
a mask stage configured to hold plural masks so that the plural masks do not contact with each other; and
a projection optical system configured to project the image of the pattern on the substrate,
wherein the projection optical system includes a plurality of optical systems,
wherein each of the plurality of optical systems projects the image of the pattern of one mask among the plural masks on an exposure area of the substrate, and
wherein the apparatus exposes the substrate so that each exposure area of the substrate exposed by each optical system partly overlaps with each other.
